(19) United States
(12) Patent Application Publication
(10) Pub. No.: US 2022/0291435 A1
(43) Pub. Date: Sep. 15, 2022

(54) PHASE RETARDATION FILM AND COMPENSATION FILM

(71) Applicant: Sichuan Longhua Film Co., Ltd., Mianyang (CN)

(72) Inventors: Ruimin DIAO, Mianyang (CN); Yao Chang WANG, Zhubei City (TW); Yi-Ping HSIEH, Hsinchu County (TW)

(21) Appl. No.: 17/371,115

(22) Filed: Jul. 9, 2021

(30) Foreign Application Priority Data
Mar. 9, 2021 (CN) 202110257864.1

(51) Int. Cl. G02B 5/30; H01L 51/52

(52) U.S. Cl. CPC G02B 5/3083; G02B 5/3016; G02B 5/3025; H01L 51/5281

(57) ABSTRACT

A phase retardation film is applied to an organic light-emitting diode display device and includes a biaxially stretched polymer substrate and a liquid crystal layer. The polymer substrate has a positive wavelength dispersion characteristic. A thickness of the polymer substrate is between 5 μm and 100 μm. The liquid crystal layer is directly coated on the polymer substrate by a full coating process, and there is no adhesion layer between the liquid crystal layer and the polymer substrate. A thickness of the liquid crystal layer is between 0.4 μm and 5 μm. One of the polymer substrate and the liquid crystal layer has a phase retardation of λ/2, and the other has a phase retardation of λ/4. A compensation film using the phase retardation film is also provided.

### FIELD OF THE INVENTION

The present invention relates to a phase retardation film and a compensation film, and more particularly to a phase retardation film and a compensation film applied to an organic light-emitting diode display device.

### BACKGROUND OF THE INVENTION

In an optical display, the phase retardation film is usually used to correct the retardation of light to improve the display effect of the optical display. For example, in an organic light-emitting diode display (OLED display), the metal electrode easily reflects the natural light in the environment and causes its contrast to decrease. Therefore, a circular polarizer formed by a linear polarizer and a phase retardation film is usually bonded to the light-emitting surface to correct the retardation of the reflected natural light so that the natural light cannot be emitted from the light-emitting surface, thereby improving the problem of natural light reflection.

However, the conventional phase retardation film can usually only perform ideal retardation correction for a single wavelength and usually have a positive wavelength dispersion characteristic, and these characteristics greatly limit its application range and performance. In addition, the conventional phase retardation film with reverse wavelength dispersion is formed by bonding two polymer layers, and this manufacturing process is complicated and the thickness of the phase retardation film is too large. As such, the conventional phase retardation film has limited application under the current trend of lightness and thinness. In addition, the conventional phase retardation film cannot be directly bonded to the polarizer through the roll-to-roll process, so the manufacture process is complicated and the cost is high.

In addition, another conventional phase retardation film with reverse wavelength dispersion is formed by bonding two liquid crystal layers. Similarly, this conventional phase retardation film still has some problems such as the thickness is too small, not easy for the subsequent process, having a color shift problem of light leakage at a large viewing angle, and having poor display effect.

### SUMMARY OF THE INVENTION

The present invention provides a phase retardation film, which is thin and capable of bonding with a linear polarizer through a roll-to-roll process.

The present invention provides a compensation film, which has the effect of simplifying the manufacturing process and reducing the production cost.

The phase retardation film provided by the present invention is applied to an organic light-emitting diode display device and includes a biaxially stretched polymer substrate and a liquid crystal layer. The polymer substrate has a positive wavelength dispersion characteristic. A thickness of the polymer substrate is between 5 μm and 100 μm. The liquid crystal layer is directly coated on the polymer substrate by a full coating process, and there is no adhesion layer between the liquid crystal layer and the polymer substrate. A thickness of the liquid crystal layer is between 0.4 μm and 5 μm. One of the polymer substrate and the liquid crystal layer has a phase retardation of 212, and the other has a phase retardation of 214.

In an embodiment of the present invention, one of the polymer substrate and the liquid crystal layer has an optical axis angle between 10 degrees and 20 degrees, and the other has an optical axis angle between 70 degrees and 80 degrees.

In an embodiment of the present invention, the polymer substrate and the liquid crystal layer form a quarter-wave plate with a reverse wavelength dispersion characteristic.

In an embodiment of the present invention, the aforementioned phase retardation film is adapted to be directly bonded with a linear polarizer through a roll-to-roll process. One of the polymer substrate and the liquid crystal layer having a phase retardation of 212 is located between the other of the polymer substrate and the liquid crystal layer having a phase retardation of 214 and the linear polarizer.

In an embodiment of the present invention, a material of the polymer substrate is polyester carbonate, cyclo olefin polymer, polyethylene terephthalate, or other polymers.

In an embodiment of the present invention, one of the polymer substrate and the liquid crystal layer has a phase retardation of 214, and an in-plane retardation is between 120 nm and 138 nm.

In an embodiment of the present invention, one of the polymer substrate and the liquid crystal layer has a phase retardation of 212, and an in-plane retardation is between 240 nm and 270 nm.

In an embodiment of the present invention, an in-plane retardation of the phase retardation film is between 150 nm and 170 nm.

In an embodiment of the present invention, the polymer substrate has a positive wavelength dispersion characteristic, in which a retardation of the polymer substrate becomes smaller as a wavelength of light becomes larger, or has a flat wavelength dispersion characteristic, in which a retardation of the polymer substrate does not change as the wavelength of light changes.

In an embodiment of the present invention, a thickness of the phase retardation film is between 5 μm and 105 μm, and an optical axis angle of the phase retardation film is between 40 degrees and 50 degrees.

The compensation film provided by the present invention is applied to an organic light-emitting diode display device and includes a phase retardation film and a linear polarizer. The phase retardation film includes a polymer substrate and a liquid crystal layer. The polymer substrate has a positive wavelength dispersion characteristic. The polymer substrate is a biaxially extending polycarbonate. An optical axis angle of the polymer substrate is between 10 degrees and 20 degrees or between 70 degrees and 80 degrees. A thickness of the polymer substrate is between 5 μm and 100 μm. The liquid crystal layer is directly coated on the polymer substrate by a full coating process. One of the polymer substrate and the liquid crystal layer has a phase retardation of λ/2, and the other has a phase retardation of λ/4. One of the polymer substrate and the liquid crystal layer has an optical axis angle between 10 degrees and 20 degrees, and the other has an optical axis angle between 70 degrees and 80 degrees. An in-plane retardation of the phase retardation film is between 150 nm and 170 nm, and an optical axis angle is between 40 degrees and 50 degrees. The linear polarizer is bonded with the phase retardation film through a roll-to-roll process. One of the polymer substrate and the liquid crystal layer having a phase retardation of 212 is located between the other of the polymer substrate and the liquid crystal layer having a phase retardation of 214 and the linear polarizer.

The phase retardation film of the embodiment of the present invention is manufactured by directly and fully coating of the liquid crystal layer on the biaxially stretched polymer substrate, so it can meet the trend of thinning the phase retardation film and can further appropriately adjust the thickness of the polymer plate. As such, the phase retardation film of the embodiment of the present invention can meet the optimal thickness requirements of different displays and can be bonded with the linear polarizer through the roll-to-roll process, thereby effectively simplifying the manufacturing process to reduce production costs and improve production efficiency.

### BRIEF DESCRIPTION OF THE DRAWINGS

The present invention will become more readily apparent to those ordinarily skilled in the art after reviewing the following detailed description and accompanying drawings, in which:

FIG. 1 is a schematic structural diagram of a phase retardation film according to an embodiment of the present invention;

FIG. 2 is a schematic structural diagram of a compensation film according to an embodiment of the present invention; and

FIG. 3 is a schematic structural diagram of a compensation film according to another embodiment of the present invention.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

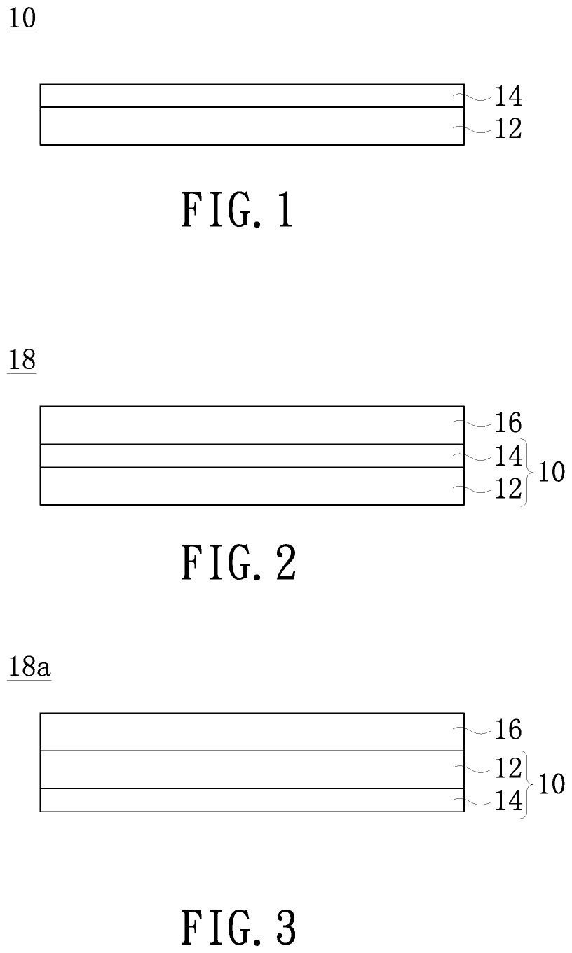

FIG. 1 is a schematic structural diagram of a phase retardation film according to an embodiment of the present invention. As shown in FIG. 1, the phase retardation film 10 includes a polymer substrate 12 and a liquid crystal layer 14. The thickness of the polymer substrate 12 is between 5 micrometers (μm) and 100 μm. In one embodiment, the polymer substrate 12 may have a positive wavelength dispersion characteristic, in which a retardation of the polymer substrate 12 becomes smaller as the wavelength of light becomes larger; or, the polymer substrate 12 may have a flat wavelength dispersion characteristic, in which a retardation of the polymer substrate 12 is almost unchanged as the wavelength of light changes. The liquid crystal layer 14 is directly coated on the polymer substrate 12 by a full coating process, and there is no adhesive layer between the liquid crystal layer 14 and the polymer substrate 12. The thickness of the liquid crystal layer 14 is between 0.4 μm and 5 μm. One of the polymer substrate 12 and the liquid crystal layer 14 has a phase retardation of a half wavelength (λ/2), and the other has a phase retardation of a quarter wavelength (λ/4).

In one embodiment, the polymer substrate 12 is, for example, a biaxially extending polycarbonate (PC) substrate. The optical axis angle of the polymer substrate 12 is between 10 degrees and 20 degrees or between 70 degrees and 80 degrees. The optical axis angle of the liquid crystal layer 14 is between 10 degrees and 20 degrees or between 70 degrees and 80 degrees. In one embodiment, the optical axis angle of the liquid crystal layer 14 is between 70 degrees and 80 degrees when the optical axis angle of the polymer substrate 12 is between 10 degrees and 20 degrees, and the optical axis angle of the liquid crystal layer 14 is between 10 degrees and 20 degrees when the optical axis angle of the polymer substrate 12 is between 70 degrees and 80 degrees. The in-plane retardation (Ro) of the polymer substrate 12 is between 120 nanometers (nm) and 138 nm, and the in-plane retardation of the liquid crystal layer 14 is between 240 nm and 270 nm.

By coating the liquid crystal layer 14 on the entire surface of the polymer substrate 12, a quarter-wave plate (i.e., the phase retardation film 10) is formed and may have a revise wavelength dispersion characteristic, in which a retardation of the phase retardation film 10 becomes larger as the wavelength of light becomes larger. In one embodiment, the in-plane retardation of the phase retardation film 10 is between 150 nm and 170 nm, the optical axis angle of the phase retardation film 10 is between 40 degrees and 50 degrees, and the thickness of the phase retardation film 10 is between 5 μm and 105 μm. In addition to carbonic acid polyester, the material of the polymer substrate 12 can be cyclo olefin polymer (COP), polyethylene terephthalate (PET), or other polymers.

In the phase retardation film 10 of the embodiment of the present invention, a polymer substrate 12 with a large area, a small thickness and a phase retardation of 212 or 214 can be formed by stretching the polymer material. Then, a large piece or even a roll of a phase retardation film 10 can be completed by directly coating the liquid crystal layer 14 on the polymer substrate 12 in a large area. FIG. 2 is a schematic structural diagram of a compensation film according to an embodiment of the present invention. In subsequent applications, the phase retardation film 10 can be bonded to a linear polarizer 16 through a roll-to-roll process to form a compensation film 18 of an organic light-emitting diode display device (not shown). As shown in FIG. 2, the liquid crystal layer 14 faces the linear polarizer 16 when the phase retardation film 10 is bonded to the linear polarizer 16, so that the liquid crystal layer 14 is located between the polymer substrate 12 and the linear polarizer 16. Preferably, a liquid crystal layer 14 with a phase retardation of 212 is located between a polymer substrate 12 with a phase retardation of 214 and the linear polarizer 16; however, the present invention is not limited thereto. FIG. 3 is a schematic structural diagram of a compensation film according to another embodiment of the present invention. As shown in FIG. 3, in the compensation film 18a, a polymer substrate 12 with a phase retardation of 212 is located between the liquid crystal layer 14 with a phase retardation of 214 and the linear polarizer 16.

Compared with the conventional phase retardation film formed by bonding two liquid crystal layers or two polymer layers, the phase retardation film 10 of the embodiment of the present invention omits the adhesion layer (adhesive layer or laminating layer) between the two liquid crystal layers or the two polymer layers, so as to meet the current demand for thinning. In addition, the phase retardation film 10 of the embodiment of the present invention itself is a quarter-wave plate, and therefore does not need to adjust the angle with respect to the linear polarizer 16 when bonding to the linear polarizer 16, which is beneficial to the roll-to-roll process of bonding and can achieve a bonding and cutting rate of about 99.9%. On the other hand, the optical compensation value of the phase retardation film 10 of the embodiment of the present invention can be effectively adjusted by adjusting the refractive index of the polymer substrate 12 (i.e., the optical characteristics of nx, ny and nz), thereby solving the light leakage problem at a large viewing angle of the conventional liquid crystal layer 14; wherein nz represents the refractive index in the thickness direction, nx represents the refractive index in the direction where the in-plane produces the maximum refractive index, and ny represents the refractive index of the direction where the in-plane is orthogonal to the nx direction.

According to the above description, the phase retardation film of the embodiment of the present invention has the effect of being thinner and capable of bonding to the linear polarizer through the roll-to-roll process, which effectively simplifies the manufacturing process of the compensation film to reduce the production cost. In addition, the thickness of the phase retardation film of the embodiment of the present invention can meet the optimal thickness requirements of different displays by appropriately adjusting the thickness of the polymer plate. In addition, the phase retardation film of the embodiment of the present invention can solve the problem of light leakage at a large viewing angle and therefore has better viewing effect.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A phase retardation film, applied to an organic light-emitting diode display device, the phase retardation film comprising:
a polymer substrate, having a positive wavelength dispersion characteristic, wherein a thickness of the polymer substrate is between 5 μm and 100 μm; and
a liquid crystal layer, directly coated on the polymer substrate by a full coating process, wherein there is no adhesion layer between the liquid crystal layer and the polymer substrate, a thickness of the liquid crystal layer is between 0.4 μm and 5 μm, one of the polymer substrate and the liquid crystal layer has a phase retardation of 212, and the other has a phase retardation of 214.

2. The phase retardation film according to claim 1, wherein one of the polymer substrate and the liquid crystal layer has an optical axis angle between 10 degrees and 20 degrees, and the other has an optical axis angle between 70 degrees and 80 degrees.

3. The phase retardation film according to claim 1, wherein the polymer substrate and the liquid crystal layer form a quarter-wave plate with a reverse wavelength dispersion characteristic.

4. The phase retardation film according to claim 1, wherein the phase retardation film is adapted to be directly bonded with a linear polarizer through a roll-to-roll process, and one of the polymer substrate and the liquid crystal layer having a phase retardation of 212 is located between the other of the polymer substrate and the liquid crystal layer having a phase retardation of 214 and the linear polarizer.

5. The phase retardation film according to claim 1, wherein a material of the polymer substrate is polyester carbonate, cyclo olefin polymer, polyethylene terephthalate, or other polymers.

6. The phase retardation film according to claim 1, wherein one of the polymer substrate and the liquid crystal layer has a phase retardation of 214, and an in-plane retardation is between 120 nm and 138 nm.

7. The phase retardation film according to claim 1, wherein one of the polymer substrate and the liquid crystal layer has a phase retardation of 212, and an in-plane retardation is between 240 nm and 270 nm.

8. The phase retardation film according to claim 1, wherein an in-plane retardation of the phase retardation film is between 150 nm and 170 nm.

9. The phase retardation film according to claim 1, wherein the polymer substrate has a positive wavelength dispersion characteristic, in which a retardation of the polymer substrate becomes smaller as a wavelength of light becomes larger, or has a flat wavelength dispersion characteristic, in which a retardation of the polymer substrate does not change as the wavelength of light changes.

10. The phase retardation film according to claim 1, wherein a thickness of the phase retardation film is between 5 μm and 105 μm, and an optical axis angle of the phase retardation film is between 40 degrees and 50 degrees.

11. A compensation film, applied to an organic light-emitting diode display device, the compensation film comprising:
a phase retardation film, comprising a polymer substrate and a liquid crystal layer, wherein the polymer substrate has a positive wavelength dispersion characteristic, a thickness of the polymer substrate is between 5 μm and 100 μm, the liquid crystal layer is directly coated on the polymer substrate by a full coating process, one of the polymer substrate and the liquid crystal layer has a phase retardation of λ/2, and the other has a phase retardation of λ/4; and
a linear polarizer, bonded with the phase retardation film through a roll-to-roll process, wherein one of the polymer substrate and the liquid crystal layer having a phase retardation of λ/2 is located between the other of the polymer substrate and the liquid crystal layer having a phase retardation of λ/4 and the linear polarizer.
